(19) United States
(12) Patent Application Publication
(10) Pub. No.: US 2011/0096516 A1
(43) Pub. Date: Apr. 28, 2011

(54) SUPPORTING ASSEMBLY FOR PRINTED CIRCUIT BOARD

(75) Inventor: ZHAN-YANG LI, Shenzhen City (CN)

(73) Assignees: HONG FU JIN PRECISION INDUSTRY (ShenZhen) CO., LTD, Shenzhen City (CN); HON HAI PRECISION INDUSTRY CO., LTD., Tu-Cheng, Taipei Hsien (TW)

(21) Appl. No.: 12/649,861

(22) Filed: Dec. 30, 2009

(30) Foreign Application Priority Data
Oct. 23, 2009 (CN) 200920313108.0

(51) Int. Cl. H05K 5/00; H05K 7/02; A47G 29/00

(52) U.S. Cl. 361/752; 361/807; 248/346.01

(57) ABSTRACT

A supporting assembly includes a chassis, a supporting member, a retaining member, a board and a fastener. The chassis defines a through hole. The supporting member includes a base, a body and the retaining recess. The body extends through the through hole. The base abuts a bottom surface of the chassis. The retaining recess is defined in the body. The retaining member engages the retaining recess and abuts a top surface of the chassis. The fastener secures the board to a top portion of the body.

### BACKGROUND

1. Technical Field

The present disclosure relates to supporting assemblies for printed circuit boards, especially to a detachable supporting assembly for a printed circuit board.

2. Description of Related Art

Printed circuit boards (PCB), such as a motherboard or an expansion card, must be firmly mounted in computer enclosures but should be mounted in a way that leaves some space between the PCB and the mounting surface. Conventionally, standoffs or rivets may be used for mounting the PCB to the enclosure but they are difficult to use while maintaining the needed space between the PCB and the enclosure.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a supporting assembly in accordance with an embodiment.

FIG. 2 is an enlarged view of a supporting member of FIG. 1.

FIG. 3 is an enlarged view of a retaining member of FIG. 1.

FIG. 4 is an assembled view of the supporting member, the retaining member, and a chassis of FIG. 1.

FIG. 5 is an assembled view of the supporting assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

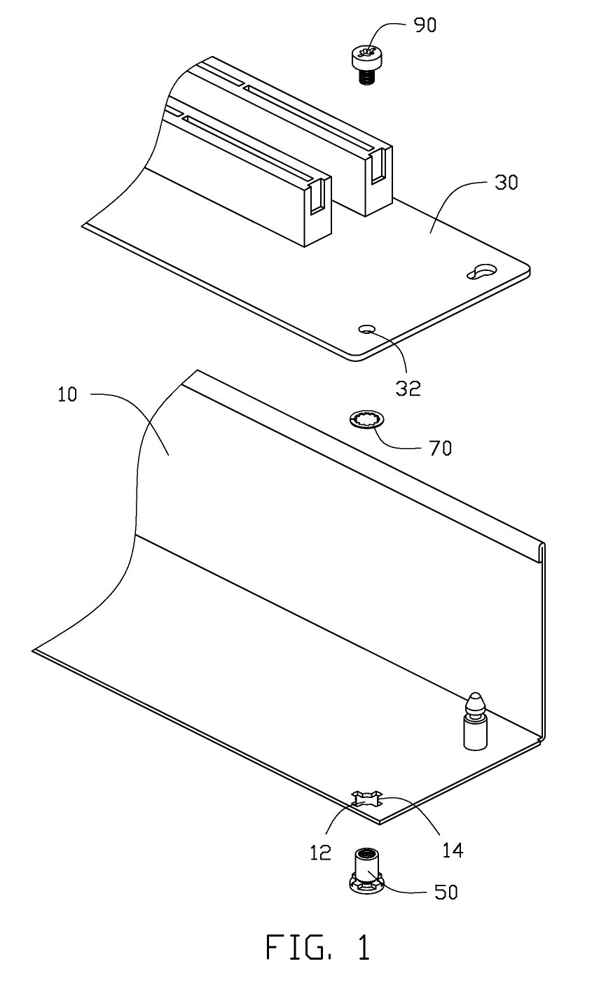

Referring to FIG. 1, a supporting assembly includes a chassis 10, a board 30, a supporting member 50, a retaining member 70, and a fastener 90. The board 30 may be supported by the supporting member 50 to space the board 30 away from the chassis 10.

The chassis 10 defines a through hole 12. Four block protrusions 14 extend from an edge of the through hole 12 at intervals. A fastener 90 has an external thread.

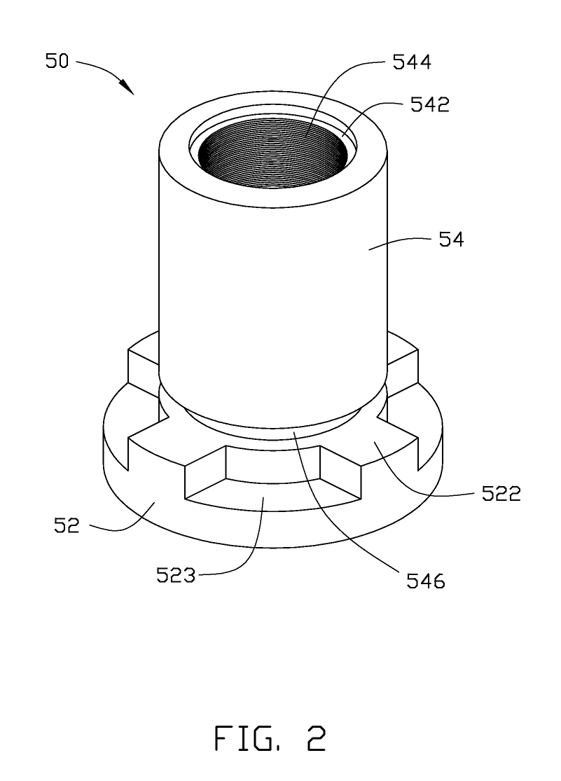

Referring to FIG. 2, the supporting member 50 includes a base 52 and a body 54 with internal thread 544 corresponding to the external thread of the fastener 90. The base 52 has a disk configuration. The base 52 is wider than the through hole 12 of the chassis 10. Four notches 523 are defined in the base 52. Two adjacent notches 523 are spaced by a raised portion 522. A thickness of each notch 523 is about equal to a thickness of the chassis 10. A retaining recess 546 is defined in the body 54 adjacent to the base 52. In the embodiment, the retaining recess 546 is a groove around the body 54. A step-like guiding slot 542 is defined at the top portion of the body 54 for guiding the fastener 90 when it is screwed into the body 54. The body 54 is narrower than the through hole 12.

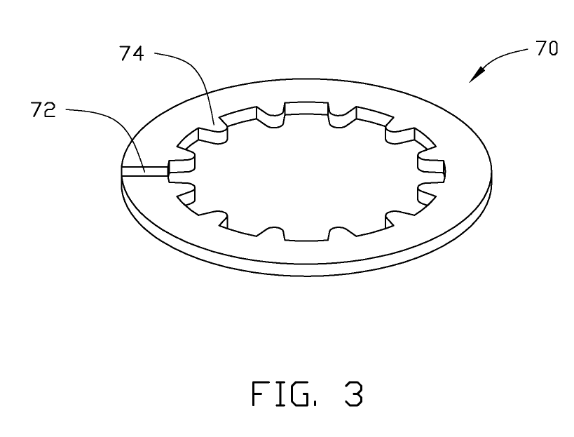

Referring to FIG. 3, the retaining member 70 has a circular configuration. A gap 72 is defined in the retaining member 70, so that the retaining member 70 may resiliently deform along a radial direction. A plurality of lobes 74 protrudes from an inner surface of the retaining member 70. The retaining member 70 is wider than the through hole 12.

The board 30 defines a mounting hole 32 for receiving the fastener 90. In one embodiment, the board 30 may be a printed circuit board, and the fastener 90 may be a screw.

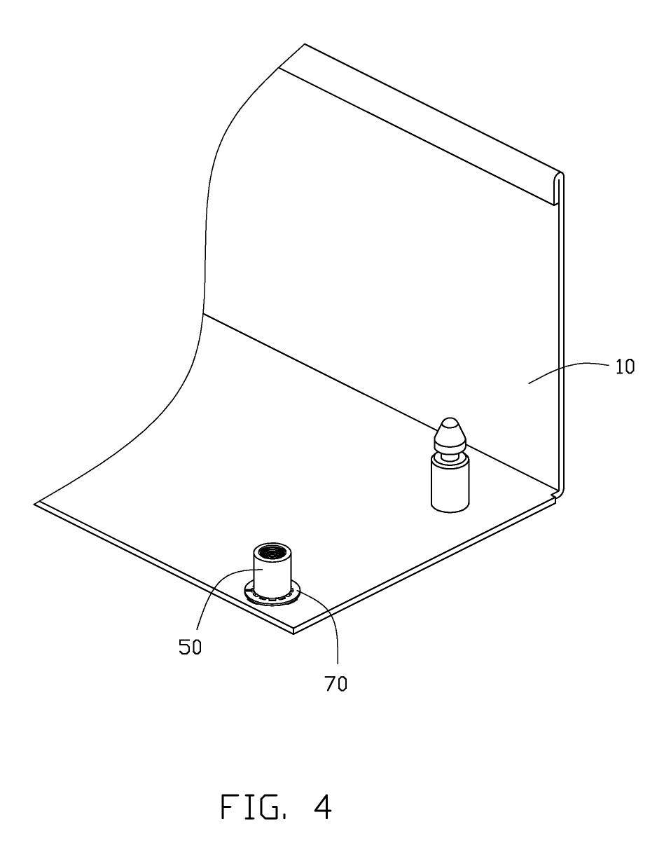

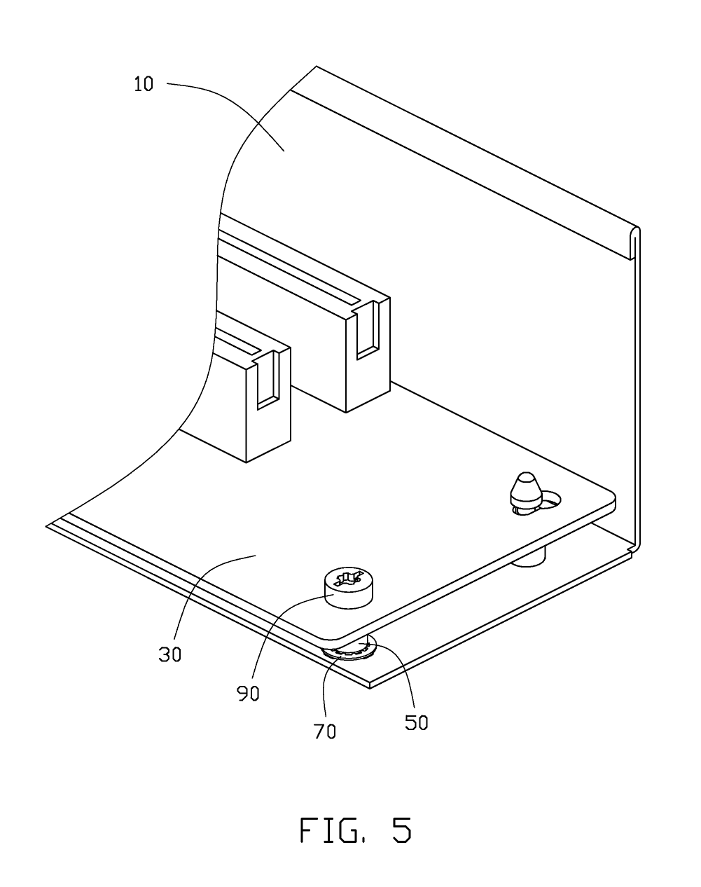

Referring also to FIG. 4 and FIG. 5, when assembling the supporting assembly, the body 54 extends through the through hole 12 of the chassis 10. The base 52 is blocked at a bottom surface of the chassis 10. The block protrusions 14 engage with the corresponding notches 546. The supporting member 50 is engaged with the retaining recess 546 with the lobes 74 abutting against the body 54. The supporting member 50 mounts the retaining member 30 at a top surface of the chassis 10. The fastener 90 extends through the mounting hole 32 and is screwed into the body 54.

It is also to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. A supporting assembly comprising:
a chassis defining a through hole;
a supporting member, the supporting member comprising a base, a body and a retaining recess, wherein the base and the body are integral, and the body extends through the through hole and the base abuts a bottom surface of the chassis, the retaining recess is defined in the body;
a retaining member, wherein the retaining member engages the retaining recess and abuts a top surface of the chassis;
a board; and
a fastener securing the board to a top portion of the body, wherein the board is spaced away from the chassis.

2. The supporting assembly of claim 1, wherein the retaining recess is a groove, and the retaining member has a circular configuration.

3. The supporting assembly of claim 2, wherein a plurality of lobes protrude from an inner surface of the retaining member, and the lobes are received in the retaining recess.

4. The supporting assembly of claim 2, wherein a gap is defined in the retaining member and the retaining member is capable of resilient radial deformation.

5. The supporting assembly of claim 1, wherein at least one notch is defined in the base, and at least one block protrusion extends from an edge of the through hole corresponding to the at least one notch.

6. The supporting assembly of claim 5, wherein a thickness of the at least one notch is about equal to a thickness of the chassis.

7. The supporting assembly of claim 5, wherein at least one raised portion is formed on the base adjacent to the at least one notch, and the at least one raised portion is capable of blocking the supporting member from rotating relative to the chassis.

8. The supporting assembly of claim 1, wherein the body has an internal thread that corresponds to an external thread on the fastener.

9. The supporting assembly of claim 1, wherein a step-like guiding slot is defined at the top portion of the body for guiding the fastener.

10. The supporting assembly of claim 1, wherein the board is a printed circuit board.

11. A supporting assembly comprising:
a chassis defining a through hole;
a supporting member, the supporting member comprising a base, a body, and the retaining recess, wherein the base and the body are integral, and the body extends through the through hole and the base abuts a bottom surface of the chassis, the retaining recess is defined in the body, the body is capable of supporting the printed circuit board away from the chassis; and
a retaining member, wherein the retaining member engages with the retaining recess and retains the supporting member at a top surface of the chassis.

12. The supporting assembly of claim 11, wherein the retaining recess is a groove, and the retaining member has a circular configuration.

13. The supporting assembly of claim 12, wherein a plurality of lobes protrudes from an inner surface of the retaining member, and the lobes are received in the retaining recess.

14. The supporting assembly of claim 12, wherein a gap is defined in the retaining member and the retaining member is capable of resilient radial deformation.

15. The supporting assembly of claim 11, wherein at least one notch is defined in the base, and at least one block protrusion extend from an edge of the through hole corresponding to the at least one notch.

16. The supporting assembly of claim 15, wherein a thickness of the at least one notch is about equal to a thickness of the chassis.

17. The supporting assembly of claim 15, wherein at least one raised portion is formed on the base adjacent to the at least one notch, and the at least one raised portion is capable of blocking the supporting member from rotating relative to the chassis.

18. The supporting assembly of claim 11, wherein the supporting assembly further comprising a fastener for retaining the printed circuit board to the body.

19. The supporting assembly of claim 18, wherein the body has an integral thread that corresponds to an external thread on the fastener.

20. The supporting assembly of claim 18, wherein a step-like guiding slot is defined at the top portion of the body for guiding the fastener.
